(19) United States
(12) Patent Application Publication
(10) Pub. No.: US 2025/0304824 A1
(43) Pub. Date: Oct. 2, 2025

(54) POLISHING COMPOSITION

(71) Applicant: FUJIMI INCORPORATED, Aichi (JP)

(72) Inventor: Yuuichi Watanabe, Aichi (JP)

(21) Appl. No.: 19/089,196

(22) Filed: Mar. 25, 2025

(30) Foreign Application Priority Data
Mar. 29, 2024 (JP) 2024-056632

(51) Int. Cl. C09G 1/02; C01B 32/21; H01L 21/3105

(52) U.S. Cl. CPC C09G 1/02; C01B 32/21; H01L 21/31053; H01L 21/31058

(57) ABSTRACT

An object of the present invention is to provide a polishing composition that can polish objects to be polished, including organic films, at a high rate. A further object of the present invention is to provide a polishing composition that can suppress remaining of abrasive grains after polishing. A polishing composition for polishing an object to be polished, comprising abrasive grains and a liquid medium, wherein the abrasive grains comprise zirconia particles, and wherein the zirconia particles have a Zr—C ratio of 5.5 to 21%.

### TECHNICAL FIELD

The present invention relates to a polishing composition.

### BACKGROUND ART

In recent years, new micromachining technologies have been developed as semiconductor integrated circuits (hereinafter, referred to as “LSI”) become more highly integrated and have higher performance. CMP is one of such technologies and is frequently used in the LSI manufacturing process (in particular, planarization of interlayer insulating materials in the multilayer wiring formation process, metal plug formation, embedded wiring formation, and the like).

In the LSI manufacturing process, films with organic compounds as the main component are sometimes used, and there are some literatures that attempt to provide polishing solutions that can polish such films with organic compounds as the main component by CMP processing. For example, Patent Literature 1 provides an abrasive solution for polishing an organic film, wherein the polishing solution has a pH of 5.0 or less and contains 2.0 to 15.0% by mass of an organic solvent with respect to the entire polishing solution, abrasive grains, and water, and wherein the abrasive grains have a degree of association, determined as secondary particle size/primary particle size, of 2.7 or less. The literature discloses that by adding an organic solvent to the polishing solution, the film with an organic compound as the main component is brought into a state where it can be easily polished (a state where reactivity is improved), and the film with an organic compound as the main component can thus be polished at a good polishing removal rate. The literature also discloses that although silica, alumina, ceria, titania, zirconia, germania, and others may be used as the abrasive grains, for example, it is preferable to use silica in terms of obtaining a high polishing removal rate for the organic film and in terms of ease of selecting the particle size of the abrasive grains, for example.

### CITATION LIST

### Patent Literature

Patent Literature 1: Japanese Patent Laid-Open No. 2011-60888

### SUMMARY OF INVENTION

### Technical Problem

An object of the present invention is to provide a polishing composition that can polish an object to be polished, including an organic film, at a high rate.

During the course of diligent investigations to solve such a problem, the present inventors have also found a new problem that abrasive grains may remain on the object to be polished after polishing. Therefore, a further object of the present invention is to provide a polishing composition that can suppress remaining of abrasive grains after polishing.

### Solution to Problem

One aspect of the present invention is a polishing composition for polishing an object to be polished, comprising abrasive grains and a liquid medium, wherein the abrasive grains comprise zirconia particles, and wherein the zirconia particles have a Zr—C ratio of 5.5 to 21%.

### Effects of the Invention

According to the present invention, there can be provided a polishing composition that can polish an object to be polished, including an organic film, at a high rate. There can also be provided a polishing composition that can suppress remaining of abrasive grains on the surface of a polished object to be polished after polishing.

### BRIEF DESCRIPTION OF THE DRAWINGS

FIG. 1 is a schematic diagram of a mechanochemical reaction caused by the use of a shaker.

FIG. 2 shows curve fitting of a C1s spectrum of XPS.

### DESCRIPTION OF EMBODIMENTS

As used herein, the expression “X to Y” is used in the sense that the numerical values listed before and after “to” (X and Y) are included as the lower limit value and the upper limit value, respectively, and means “X or more and Y or less”. If “X to Y” is listed more than once, for example, if “X1 to Y1 or X2 to Y2” is described, the disclosure of each numerical value as the upper limit, the disclosure of each numerical value as the lower limit, and the combination of those upper and lower limits are all disclosed (that is, they serve as the lawful basis for amendment). Specifically, amendment with X1 and more, amendment with Y2 and less, amendment with X1 and less, amendment with Y2 and more, amendment with X1 to X2, amendment with X1 to Y2, and others must all be considered lawful. In addition, unless otherwise specified, operations and measurements of physical properties and the like are performed under conditions of room temperature (20 to 25° C.)/relative humidity of 40 to 50% RH. Note that the concentration described herein may be the concentration at the point of use (POU) or may be the concentration prior to dilution to the concentration at the POU. The dilution factor may be 2 to 10 times. In addition, it must be understood that all combinations of embodiments and descriptions disclosed herein are disclosed in the present application. That is, it must be understood that they can be the basis for amendment. Also, when there is a description on the content or concentration of each component, it can be the total amount when two or more types of it are contained.

### <Polishing Composition>

The present invention is a polishing composition for polishing an object to be polished, comprising abrasive grains and a liquid medium, wherein the abrasive grains comprise zirconia particles, and wherein the zirconia particles have a Zr—C ratio of 5.5 to 21%. Such a configuration can provide a polishing composition that can polish an object to be polished, including an organic film, at a high rate. There can also be provided a polishing composition that can suppress remaining of abrasive grains on the surface of a polished object to be polished after polishing.

### [Object to be Polished]

The object to be polished preferably includes an organic film, and more preferably includes a graphite component-containing material. Examples of the object to be polished include graphene, graphite, amorphous carbon, spin-on carbon (SOC), and diamond-like carbon (DLC), and in particular, it is preferable to have a layered material of carbon atoms having sp² hybrid orbitals, such as graphene or graphite. Films having the above object to be polished can be formed by CVD, PVD, or spin coating methods, for example.

The object to be polished may have silicon oxide, monocrystalline silicon, polycrystalline silicon (polysilicon), amorphous silicon, polycrystalline silicon doped with n-type or p-type impurities, amorphous silicon doped with n-type or p-type impurities, metal simple substance, SiGe, or other materials. Examples of the object to be polished that contains silicon oxide include a TEOS (tetraethyl orthosilicate)-type silicon oxide surface produced using tetraethyl orthosilicate as a precursor. Examples of the metal simple substance include tungsten, copper, cobalt, hafnium, nickel, gold, silver, platinum, palladium, rhodium, ruthenium, iridium, and osmium.

According to one embodiment of the present invention, the object to be polished is substantially free of a material having metal-nitrogen bonds. Examples of the materials having metal-nitrogen bonds include silicon nitride (SiN), tantalum nitride (TaN), and titanium nitride (TIN). The object to be polished being substantially free of a material having metal-nitrogen bonds means that the object to be polished is free of a material having metal-nitrogen bonds, or even if it does contain such materials, they are at or below the detection limit.

### [Abrasive Grains]

In the present invention, the abrasive grains include zirconia particles with a Zr—C ratio of 5.5 to 21%. By using such abrasive grains, it is possible to polish an object to be polished (organic film, in particular, a layered material of carbon atoms having sp² hybrid orbitals, such as graphite) at a high rate, and to suppress remaining of abrasive grains (zirconia particles) after polishing.

The following is a description for a mechanism that does not restrict the present invention. First of all, the Zr—C ratio is an index that indicates the degree of covalent bonds between the zirconium atoms constituting the zirconia and the carbon atoms that may be contained in the object to be polished. A high Zr—C ratio facilitates the formation of covalent bonding, and vice versa at a low ratio. The Zr—C ratio of the zirconia particles is, in plain words, an index of the ease of forming a covalent bonding being formed between the zirconium atoms contained in the zirconia particles and the carbon atoms that may be contained in the object to be polished. It does not mean that carbon atoms are contained in the zirconia particles. In a more specific example, the Zr—C ratio is confirmed by schematically/simulatively reproducing the environment when polishing graphite with zirconia particles, that is, the environment in which mechanical stress is generated when zirconia particles are pressed against the surface to be polished by the polishing pad or the like and are in sliding contact with graphite, by forcibly inducing a mechanochemical reaction between zirconia and graphite with the use of a shaker (see the section <Measurement of Zr—C Ratio> in Examples). Since the zirconia particles of the present invention have a Zr—C ratio of 5.5% or more and thus easily form covalent bonding with carbon atoms, when the object to be polished is, in particular, a layered material of carbon atoms having sp² hybrid orbitals, such as graphite, covalent bonds (Zr—C) are easily formed between the zirconium atoms constituting the zirconia and the carbon atoms having sp² hybrid orbitals, such as graphite. Since the energy of the formed covalent bonding (Zr—C) is stronger than the interlayer binding energy in the graphite structure, delamination of the graphite structure is easily induced when the zirconia particles pressed against the object to be polished by the polishing pad are in sliding contact with the object to be polished. On the other hand, if the Zr—C ratio is more than 21%, that is, the formation of covalent bonds (Zr—C) with the carbon atoms is excessively encouraged, the binding strength with the layered material of carbon atoms having sp² hybrid orbitals, such as graphite, becomes too strong, increasing the number of zirconia particles remaining after polishing. In the present invention, since the Zr—C ratio of the zirconia particles included in the abrasive grains is 21% or less, excessive covalent bonds (Zr—C) are not formed and remaining of the abrasive grains can be suppressed. In this manner, by setting the Zr—C ratio of the zirconia particles to 5.5% or more, the covalent bonds (Zr—C) with the object to be polished can be made sufficient and the polishing removal rate can be improved. Also, by setting the Zr—C ratio to 21% or less, the formation of covalent bonding (Zr—C) with the object to be polished can be made appropriate, and remaining of the abrasive grains after polishing can be suppressed. Hence, the abrasive grains of the present invention preferably include those capable of covalent bonding with the object to be polished.

According to one embodiment of the present invention, the Zr—C ratio of the zirconia particles is 5.8% or more, 6.0% or more, 8.0% or more, 10.0% or more, 12.0% or more, 14.0% or more, or 16.0% or more. According to one embodiment of the present invention, the Zr—C ratio of the zirconia particles is 20% or less, 18% or less, 16% or less, 14% or less, 13% or less, or 11% or less. Having such upper and lower limits can significantly improve the polishing removal rate for the object to be polished and can suppress remaining of the abrasive grains after polishing.

According to one embodiment of the present invention, the polishing composition is substantially free of a component that inhibits the covalent bonding (Zr—C) described above. By being substantially free of a component that inhibits the covalent bonding, the polishing removal rate for the object to be polished can be improved. Here, the polishing composition being substantially free of a component that inhibits the covalent bonding (Zr—C) described above means that the polishing composition is completely free of a component that inhibits the covalent bonding (Zr—C) described above (at or below the detection limit), or even if it contains such a component, it is less than 0.00001% by mass in the polishing composition. Typical example of the component that inhibits the covalent bonding include a water-soluble polymer (in particular, a water-soluble polymer having a polar group), a surfactant (in particular, an anionic surfactant having an anionic group), and a non-aromatic crosslinked cyclic compound. Hence, according to one embodiment of the present invention, the component that inhibits the covalent bonding described above is a water-soluble polymer. Here, a surfactant refers to a compound having at least one or more hydrophilic moieties (typically a hydrophilic group) and one or more hydrophobic moieties (typically a hydrophobic group) in one molecule. In addition, the term “water-soluble” means that the solubility in water (25° C.) is 1 g/100 mL or more, and the term “polymer” refers to a (co) polymer that has repeating units in its molecular structure and has a weight average molecular weight (Mw) of 1,000 or more. Herein, for the “weight average molecular weight”, the value of the weight average molecular weight (in terms of polyethylene glycol) as measured by gel permeation chromatography (GPC) can be used.

According to one embodiment of the present invention, the zirconia particles are preferably colloidal zirconia particles or milled/calcined zirconia particles, and are more preferably colloidal zirconia particles. In addition, the zirconia particles may be undoped, or may be doped with, for example, yttrium (Y) or calcium (Ca), or an oxide thereof. Preferably, the zirconia particles are colloidal zirconia particles doped with yttrium (Y) or an oxide thereof. The following is a description for Y-stabilized zirconia particles doped with yttrium (Y) or an oxide thereof.

The concentration (% by mol) of yttrium (in terms of yttria) in Y-stabilized zirconia particles is defined as follows. Note that the concentration of yttrium may be adjusted by, for example, adding an yttrium carboxylate.

$${Y}_{2} {O}_{3} ( \% by mol ) = \{ ( mol of {Y}_{2} {O}_{3} ) / [ ( mol of {Y}_{2} {O}_{3} ) + ( mol of {ZrO}_{2} ) ] \} \times 100 \qquad [ Expression 1 ]$$

The % by mol of yttrium can be determined by the X-ray fluorescence (XRF) method, or by any other method known in the art. The concentration of yttrium in the Y-stabilized zirconia particles is at least 3% by mol, 4% by mol, 5% by mol, 6% by mol, 7% by mol, 8% by mol, 9% by mol, 10% by mol, 11% by mol, 12% by mol, 13% by mol, 14% by mol, or 15% by mol. In addition, the concentration of yttrium in the Y-stabilized zirconia particles is 45% by mol, 40% by mol, 35% by mol, 30% by mol, 25% by mol, or less than 20% by mol. The concentration of yttrium in the Y-stabilized zirconia particles is 1, 2, 3, 4, 5, 6, 7, 8, 9, 10, 11, 12, 13, 14, 15, 16, 17, 18, 19, 20, 21, 22, 23, 24, or 25% by mol, or in the range therebetween.

The concentration of yttrium in the Y-stabilized zirconia particles is 0.2% by mol or more or less, 1% by mol or more or less, 2% by mol or more or less, 3% by mol or more or less, 4% by mol or more or less, 5% by mol or more or less, 6% by mol or more or less, 7% by mol or more or less, 8% by mol or more or less, 9% by mol or more or less, 10% by mol or more or less, 11% by mol or more or less, 12% by mol or more or less, 13% by mol or more or less, 14% by mol or more or less, 15% by mol or more or less, 16% by mol or more or less, 17% by mol or more or less, 18% by mol or more or less, 19% by mol or more or less, 20% by mol or more or less, 21% by mol or more or less, 22% by mol or more or less, 23% by mol or more or less, 24% by mol or more or less, or 25% by mol or more or less. Note that the concentration of yttrium in the colloidal zirconia particles in Examples of the present invention can be 0.3 to 17% by mol.

In some embodiments, the Y-stabilized zirconia particles contain a monoclinic phase (for example, yttrium in the Y-stabilized zirconia particles is in a sufficient concentration to bring about a monoclinic phase). In some embodiments, the Y-stabilized zirconia particles contain a tetragonal phase (for example, yttrium in the Y-stabilized zirconia particles is in a sufficient concentration to bring about a tetragonal phase). In some embodiments, the Y-stabilized zirconia particles contain a cubic phase (for example, yttrium in the Y-stabilized zirconia particles is in a sufficient concentration to bring about a cubic phase). Note that the expression “X (X is a numerical value) or more or less” described herein means that it may be X or more or may be X or less herein. That is, when making amendment, the numerical value X can be the basis for the lower limit value, or can be the basis for the upper limit value.

It is preferable that the abrasive grains (in particular, zirconia particles) according to the present invention have a diameter of particles where the cumulative particle volume from the finer particle side reaches 50% of the entire particle volume (D50, hereinafter also simply referred to as “D50”) in the particle size distribution determined by the laser diffraction scattering method is 5 nm or more and 150 nm or less. When the D50 of the abrasive grains (in particular, zirconia particles) is less than 5 nm, the polishing removal rate is extremely reduced. On the other hand, if the D50 of the abrasive grains (in particular, zirconia particles) exceeds 150 nm, scratches may occur on the surface after polishing. The D50 of the abrasive grains (in particular, zirconia particles) can be 10 nm or more, 25 nm or more, 30 nm or more, 40 nm or more, 50 nm or more, 60 nm or more, 70 nm or more, 80 nm or more, or 90 nm or more. In addition, the D50 of the abrasive grains (in particular, zirconia particles) can be 110 nm or less, 90 nm or less, 80 nm or less, 70 nm or less, 60 nm or less, 50 nm or less, 40 nm or less, or 30 nm or less. The D50 of the abrasive grains (in particular, zirconia particles) can be measured more specifically by the method described in Examples.

There is no particular restriction on the shape of the abrasive grains (in particular, zirconia particles), and it may be spherical or may be non-spherical. Specific examples of the non-spherical shape include, but are not particularly restricted to, various shapes such as a polygonal columnar shape such as a triangle pole and a square pole, a cylindrical shape, a straw bag shape in which the center part of the cylinder is swollen more than the end parts, a donut shape in which the center part of the disk is hollow, a plate shape, a so-called cocoon type shape having a constriction at the center part, a so-called associated type spherical shape in which a plurality of particles are integrated, a so-called kompeito shape having a plurality of protrusions on the surface, a rod shape, a diamond shape, a horn shape, and a rugby ball shape.

There is no particular restriction on the lower limit of the zeta potential of the abrasive grains (in particular, zirconia particles) in the polishing composition, but it can be 5 mV or more, 10 mV or more, 20 mV or more, 25 mV or more, 30 mV or more, 32 mV or more, or 35 mV or more. In addition, there is no particular restriction on the upper limit of the zeta potential of the abrasive grains (in particular, zirconia particles) in the polishing composition, but it can be 70 mV or less, 65 mV or less, 55 mV or less, 50 mV or less, 45 mV or less, 40 mV or less, 35 mV or less, 33 mV or less, 31 mV or less, 29 mV or less, or 28 mV or less.

As used herein, as the zeta potential of the abrasive grains (in particular, zirconia particles), the value as measured by the method described in Examples is employed. The zeta potential of the abrasive grains (in particular, zirconia particles) can be adjusted by the pH and other factors of the polishing composition.

There is no particular restriction on the content (concentration) of the abrasive grains (in particular, zirconia particles) in the polishing composition, but it can be 0.01% by mass or more, 0.05% by mass or more, 0.08% by mass or more, 0.1% by mass or more, 0.2% by mass or more, 0.3% by mass or more, or 0.4% by mass or more with respect to the total mass of the polishing composition. In addition, the upper limit of the content of the abrasive grains (in particular, zirconia particles) in the polishing composition can be 10% by mass or less, 5% by mass or less, 4% by mass or less, 3% by mass or less, 2% by mass or less, 1% by mass or less, or 0.8% by mass or less with respect to the total mass of the polishing composition.

In the polishing composition according to the present invention, the abrasive grains may further include other abrasive grains other than the zirconia particles to such an extent that the effects of the present invention are not inhibited. Such other abrasive grains may be any of inorganic particles, organic particles, and organic-inorganic composite particles. Specific examples of the inorganic particles include particles composed of metal oxides such as unmodified silica, cation-modified silica, alumina, ceria, and titania, silicon nitride particles, silicon carbide particles, and boron nitride particles. Specific examples of the organic particles include polymethyl methacrylate (PMMA) particles. As such other abrasive grains, one type alone or a combination of two or more types may be used. In addition, as such other abrasive grains, commercial products may be used, or synthetic products may be used. If particles other than the zirconia particles are also used as such other abrasive grains in combination, they are preferably silica or ceria. Ceria can be suitably used together with the zirconia particles from the viewpoint that it can form covalent bonding with the object to be polished.

However, the content of such other abrasive grains is preferably 20% by mass or less, more preferably 10% by mass or less, still more preferably 5% by mass or less, and particularly preferably 1% by mass or less, with respect to the entire mass of the abrasive grains. Most preferably, the content of such other abrasive grains is 0% by mass, that is, the abrasive grains are in the form composed solely of the zirconia particles.

### [Liquid Medium]

The polishing composition of the present invention contains a liquid medium. Examples of the liquid medium can include water, alcohols such as methanol, ethanol, and ethylene glycol, ketones such as acetone, and mixtures thereof. Of these, water is preferable as the liquid medium. That is, according to a preferred embodiment of the present invention, the liquid medium includes water. According to a more preferred embodiment of the present invention, the liquid medium is substantially composed of water. Note that the term “substantially” described above is intended to mean that a liquid medium other than water can be included as long as the intended effects of the present invention can be achieved, and more specifically, the liquid medium is preferably composed of 90% by mass or more and 100% by mass or less of water and 0% by mass or more and 10% by mass or less of a liquid medium other than water, and is more preferably composed of 99% by mass or more and 100% by mass or less of water and 0% by mass or more and 1% by mass or less of a liquid medium other than water. Most preferably, the liquid medium is water.

From the viewpoint of not inhibiting the action of the components contained in the polishing composition, water containing as few impurities as possible is preferable as the liquid medium, and specifically, pure water or ultrapure water obtained by removing impurity ions with an ion exchange resin and then passing the water through a filter to remove foreign substances, or distilled water is more preferable.

### [pH and pH Adjusting Agent]

The pH of the polishing composition according to the present invention is, for example, less than 6, 5.9 or less, 5.7 or less, 5.5 or less, or less than 5.5. When the pH of the polishing composition is less than 6, the stability of the polishing composition is more improved. The pH of the polishing composition according to the present invention is preferably more than 2, 2.4 or more, 2.8 or more, 3.2 or more, 3.6 or more, 3.7 or more, or more than 3.7. When the pH of the polishing composition is 2 or less, the polishing removal rate for the graphite component-containing material (in particular, a layered material of carbon atoms having sp² hybrid orbitals, such as graphite) as the object to be polished may be decreased. Hence, according to one embodiment of the present invention, the pH of the polishing composition is more than 3.7 and less than 5.5.

The polishing composition according to the present invention can contain a pH adjusting agent for adjusting the pH. The pH adjusting agent may be any of inorganic acids, organic acids, and bases. As the pH adjusting agent, one type alone or a combination of two or more types may be used.

Specific examples of the inorganic acids that can be used as the pH adjusting agent include hydrochloric acid, sulfuric acid, nitric acid, hydrofluoric acid, boric acid, carbonic acid, hypophosphorous acid, phosphorous acid, and phosphoric acid. Of these, hydrochloric acid, sulfuric acid, nitric acid, or phosphoric acid is preferable.

Specific examples of the organic acids that can be used as the pH adjusting agent include formic acid, acetic acid, camphorsulfonic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, phenoxyacetic acid, methanesulfonic acid, ethanesulfonic acid, and isethionic acid.

Specific examples of the bases that can be used as the pH adjusting agent include ammonia, sodium hydroxide, potassium hydroxide, and tetramethylammonium hydroxide. There is no particular restriction on the amount of the pH adjusting agent added, and it may be adjusted as appropriate such that the polishing composition has the desired pH.

The pH adjusting agent contained in the polishing composition according to the present invention is preferably an inorganic acid such as nitric acid, compared to organic acids such as acetic acid or camphorsulfonic acid.

According to one embodiment of the present invention, the polishing composition is free of an alkali compound. When the polishing composition contains an alkali compound, an aggregation of the abrasive grains proceeds and the ground contact area of the abrasive grains with the object to be polished is increased, which may lead to an increase in particle residues. The alkali compound can be a substance that is dissolved in water (25° C.) to exhibit basicity, and neutralize acids. Examples of the alkali compounds include ammonia, potassium hydroxide, amine compounds such as AEPD (2-amino-2-ethyl-1,3-propanediol), DGA (diglycolamine), and tetramethylammonium hydroxide, basic amino acids, and nitrogen-containing heterocyclic compounds having an isothiazolinone skeleton.

The pH of the polishing composition can be measured with, for example, a pH meter, and specifically, can be measured by the method described in Examples.

### [Other Components]

The polishing composition according to the present invention may further contain, or may be free of a known additive that can be used for the polishing composition, such as an oxidizing agent, a complexing agent, an antiseptic agent, and an antifungal agent, to such an extent that the effects of the present invention are not inhibited.

Examples of the oxidizing agent include hydrogen peroxide, sodium peroxide, barium peroxide, ozonated water, silver (II) salts, iron (III) salts, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and salts thereof. One of these oxidizing agents may be used alone, or two or more oxidizing agents may be used in combination. Of these, hydrogen peroxide, potassium permanganate, sodium permanganate, ammonium persulfate, periodic acid, hypochlorous acid, and sodium dichloroisocyanurate are preferable, hydrogen peroxide, potassium permanganate, and sodium permanganate are more preferable, and potassium permanganate is still more preferable.

According to one embodiment of the present invention, the lower limit of the content of the oxidizing agent in the polishing composition is 0.001% by mass or more, or 0.01% by mass or more. According to one embodiment of the present invention, the upper limit of the content of the oxidizing agent in the polishing composition is 30% by mass or less, 10% by mass or less, or 1% by mass or less, 0.01% by mass or less, or less than 0.001% by mass.

According to one embodiment of the present invention, the polishing composition is substantially free of a metal-containing oxidizing agent. The metal in the metal-containing oxidizing agent includes, for example, manganese, cerium, vanadium, and iron. Examples of the metal-containing oxidizing agents include KMnO₄, (NH₄)₂Ce(NO₃)₆, NaVO₃, NH₄VO₃, and Fe(NO₃)₃. The expression “the polishing composition is substantially free of a metal-containing oxidizing agent” includes the case where the polishing composition is completely free of a metal-containing oxidizing agent (at or below the detection limit), as well as the case where less than 0.05 mM of a metal-containing oxidizing agent is contained. In the present invention, the abrasive grains that include zirconia particles with a Zr—C ratio of 5.5 to 21% are used, and therefore, the object to be polished (organic film, in particular, a layered material of carbon atoms having sp² hybrid orbitals, such as graphite) can be polished at a high rate without containing metal-containing oxidizing agents. In addition, the fact that the polishing composition is substantially free of a metal-containing oxidizing agent can suppress remaining of the metal component on the polished surface, and can also significantly suppress the occurrence of current leakage. Moreover, the fact that the polishing composition is substantially free of a metal-containing oxidizing agent facilitates the waste water treatment, which is also environmentally friendly.

According to one embodiment of the present invention, the polishing composition is substantially substantially free of an oxidizing agent, except for nitric acid. The expression “the polishing composition is substantially substantially free of an oxidizing agent, except for nitric acid” includes the case where the polishing composition is completely free of an oxidizing agent, except for nitric acid (at or below the detection limit), as well as the case where less than 0.001% by mass of an oxidizing agent is contained. In the present invention, the abrasive grains that include zirconia particles with a Zr—C ratio of 5.5 to 21% are used, and therefore, the object to be polished (organic film, in particular, a layered material of carbon atoms having sp² hybrid orbitals, such as graphite) can be polished at a high rate without containing oxidizing agents, except for nitric acid. The fact that the polishing composition is substantially substantially free of an oxidizing agent, except for nitric acid improves storage stability.

### [Method for Manufacturing Polishing Composition]

Next, a method for manufacturing the polishing composition of the present invention will be described. There is no particular restriction on the method for manufacturing the polishing composition according to the present invention, and it can be obtained by, for example, stirring and mixing abrasive grains that include specific zirconia particles and, if necessary, other additives, in a liquid medium (preferably in water). The details of each component are as described above.

There is no particular limitation on the method for manufacturing zirconia particles with a Zr—C ratio of 5.5 to 21%, and they can be prepared by referring to previously known methods as appropriate, for example. For example, the zirconia particles are made to be particles with appropriate hardness and the Zr—C ratio is easily controlled to be in a predetermined range by selecting the following manufacturing methods and manufacturing conditions as appropriate to meet a predetermined purpose: a method in which a mixed aqueous solution obtained by dissolving a carboxylic acid salt of yttrium and zirconium oxyacetate in water in a specific ratio range is subjected to a hydrothermal treatment, thereby obtaining an yttrium oxide-stabilized zirconium oxide aqueous sol with almost no secondary aggregation of colloidal particles and with extremely good transparency (see International Publication No. WO 2010/071135); a method in which calcia-stabilized zirconia powder with a full width at half maximum of the powder X-ray diffraction spectrum main peak at or below a certain angle is manufactured by performing the following steps: neutralizing an aqueous solution of a zirconium salt and preparing a slurry from which the produced salt has been removed; adding a predetermined amount of a predetermined calcium compound to the slurry and heating the mixture to 80 to 100° C. (see Japanese Patent Laid-Open No. 2020-75859); and a method in which zirconia powder is manufactured by preparing a raw material blend by the neutralization coprecipitation method or the like to achieve predetermined raw material compositional features, calcining it at a predetermined temperature (500 to 1200° C.), forming the raw material powder obtained through a disintegration step, and then sintering it at a predetermined temperature (1300 to 1650° C.) (Japanese Patent Laid-Open No. 09-188562). For example, in the case of International Publication No. WO 2010/071135, zirconia particles can be easily controlled to have a predetermined Zr—C ratio by raising the temperature of the hydrothermal treatment disclosed therein (for example, 290° C. or higher or 400° C. or higher in particular, and 600° C. or lower as the upper limit), for example. Also, in the case of Japanese Patent Laid-Open No. 2020-75859, it is easier to obtain the Zr—C ratio of zirconia particles by increasing the solution concentration (concentration of the zirconium salt) (for example, more than 1.0 mol/kg or 1.5 mol/kg or more, and 3.0 mol/kg or less as the upper limit), for example. In addition, in the case of Japanese Patent Laid-Open No. 09-188562, the Zr—C ratio of zirconia particles is easily controlled to be in a predetermined range by increasing the calcination temperature for sintering (for example, 1700° C. or higher, 1900° C. or higher, and 2200° C. or lower as the upper limit), for example. Moreover, the method for manufacturing the polishing composition of the present invention may have a confirmation step of confirming the Zr—C ratio of zirconia particles, thereby manufacturing abrasive grains that include zirconia particles with a Zr—C ratio of 5.5 to 21%. Note that commercially available products of zirconia particles with a Zr—C ratio of 5.5 to 21% may also be used if available. The contents disclosed in these Publications are incorporated herein by reference in their entirety.

There is no particular restriction on the temperature at which each component is mixed, but it is preferably 10° C. or higher and 40° C. or lower, and may be heated to increase the rate of dissolution. There is no particular restriction on the mixing time either, as long as uniform mixing can be achieved.

### [Polishing Method and Method for Manufacturing Semiconductor Substrate]

As described above, the polishing composition according to the present invention is suitably used for polishing an object to be polished (organic film, in particular, a layered material of carbon atoms having sp² hybrid orbitals, such as graphite). Hence, the present invention provides a method of polishing an object to be polished (organic film, in particular, a layered material of carbon atoms having sp² hybrid orbitals, such as graphite) with the polishing composition according to the present invention. The present invention also provides a method for manufacturing a substrate (including an organic film, in particular, a layered material of carbon atoms having sp² hybrid orbitals, such as graphite), the method including polishing the substrate by the polishing method described above.

The polishing apparatus that can be used may be any general polishing apparatus to which a holder that holds a substrate or the like having an object to be polished, a motor whose rotation speed can be changed, and other components are attached, and that have a polishing table to which a polishing pad (polishing cloth) can be pasted.

As the polishing pad, general non-woven fabrics, polyurethanes, porous fluororesins, and others can be used with no particular restriction. It is preferable that the polishing pad has been grooved to allow the polishing solution to accumulate.

Regarding the polishing conditions, for example, the rotation speed of the polishing table and carrier is preferably 10 rpm (0.17 s⁻¹) or more and 500 rpm (8.33 s⁻¹) or less. The pressure applied to the substrate having an object to be polished (polishing pressure) is preferably 0.5 psi (3.4 kPa) or more and 10 psi (68.9 kPa) or less.

There is no particular restriction on the method for supplying the polishing composition to the polishing pad either, and for example, a method is employed in which the polishing composition is continuously supplied with a pump or the like. There is no restriction on the amount supplied, but it is preferable that the surface of the polishing pad may always be covered with the polishing composition according to the present invention.

After completion of polishing, the substrate is cleaned in running water, water droplets adhered onto the substrate are removed using a spin dryer or the like for drying, and thus the substrate having a metal-containing layer is obtained.

The polishing composition according to the present invention may be of a single-fluid type or multi-fluid type including double-fluid type. In addition, the polishing composition according to the present invention may be prepared by, for example, diluting 2 to 10 times an undiluted solution of the polishing composition using a diluent such as water.

The present invention encompasses the following aspects and forms.

1. A polishing composition for polishing an object to be polished, comprising abrasive grains and a liquid medium, wherein the abrasive grains comprise zirconia particles, and wherein the zirconia particles have a Zr—C ratio of 5.5 to 21%.

2. The polishing composition according to 1., wherein the object to be polished comprises a graphite component-containing material.

3. The polishing composition according to 2., wherein the object to be polished comprises a layered material of carbon atoms having sp² hybrid orbitals.

4. The polishing composition according to any of 1. to 3., wherein the abrasive grains comprise those capable of covalent bonding with the object to be polished.

5. The polishing composition according to 4., which is free of a component that inhibit the covalent bonding.

6. The polishing composition according to 5., wherein the components that inhibit the covalent bonding are water-soluble polymers.

7. The polishing composition according to any of 1. to 6., wherein the object to be polished is substantially free of a material having metal-nitrogen bonds.

8. The polishing composition according to any of 1. to 7., which is free of an alkali compound.

9. The polishing composition according to any of 1. to 8., which is substantially free of a metal-containing oxidizing agent.

10. The polishing composition according to any of 1. to 9., which is substantially free of an oxidizing agent, except for nitric acid.

11. The polishing composition according to any of 1. to 10., having a pH of less than 6.

12. The polishing composition according to 11., having a pH of more than 3.7 and less than 5.5.

### EXAMPLES

The present invention will be described in further detail using the following Examples and Comparative Examples. However, the technical scope of the present invention is not restricted to the following Examples alone. Note that, unless otherwise specified, “%” and “part(s)” refer to “% by mass” and “parts by mass”, respectively.

### [Evaluation of Physical Properties and Others]

### <Measurement of Zr—C Ratio>

### (Fabrication of Zirconia/Graphite Mixture)

As described below, an aqueous dispersion of the zirconia particles of Example 1 was prepared. This was placed in a glass beaker and heated in a water bath set to 100° C. to remove moisture. The resulting dried material was disintegrated in a mortar for a predetermined time to form powdered particles.

In addition, graphite powder was prepared from FUJIFILM Wako Pure Chemical Corporation.

The zirconia/graphite mixture (ZrO₂/graphite) was prepared by weighing 4 mL of each of the zirconia particles and graphite powder in a measuring cylinder and mixing them lightly using a spatula in a 50 mL resin vessel.

### (Mechanochemical Reaction of Mixture)

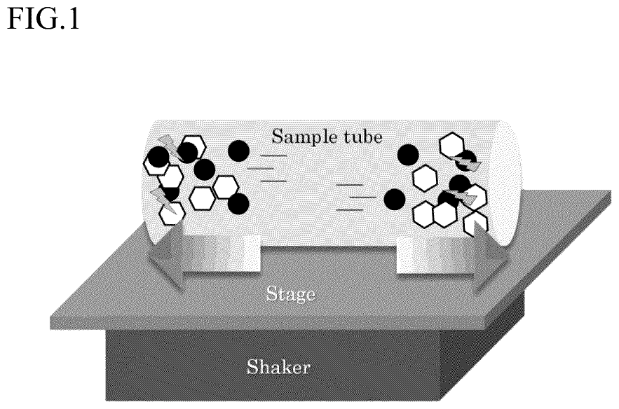

Using a reciprocating shaker, a resin vessel (sample tube) in which the mixture described above was placed was subjected to a stirring treatment at room temperature and under normal pressure. FIG. 1 shows its schematic diagram. By causing the particles to forcibly collide with each other in this manner, a mechanochemical reaction was forcibly induced to afford the reaction product. The rotation speed at the time of shaking was set to 200 rpm, and the treatment time was set to 60 minutes. In addition, as a comparative sample, the same shaking test was also carried out for graphite powder alone.

### (XPS Analysis)

The various reaction products obtained by the shaking treatment were sprinkled on a sample table to which carbon tape had been pasted, pressed through a piece of drug packing paper, and then the excess was removed by air blow. For the XPS measurement, PHI5000 VersaProbe II (manufactured by ULVAC-PHI, Inc.) was used. At this time, the chamber vacuum degree was 5.0×10⁻⁸ Pa, and as the excitation X-ray conditions, the source was Al-Kα ray, the output was 25 W, and the irradiation range was 100 μmφ. The detection conditions were as follows: pass energy was 46.95 eV, the eV step was 0.1 eV, the detection angle was 45 degrees, the detection time was 20 ms/step, the cumulative number was 20 times, and the C1s (277 to 297 eV) spectrum was collected at n=8.

### (Calculation of Zr—C Ratio)

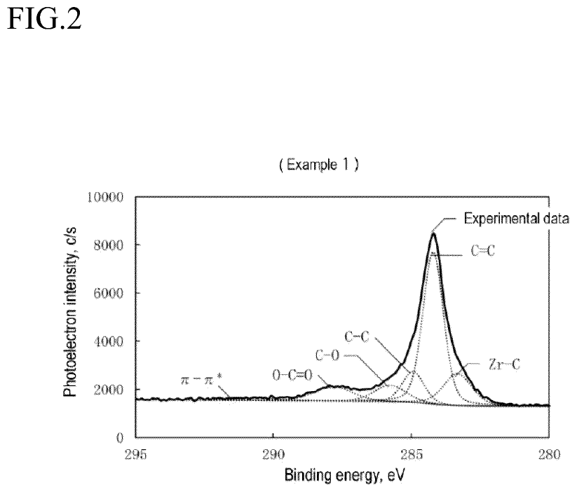

Waveform separation of the C1s spectrum was carried out using the analysis software MultiPak ver. 9.9.3 (manufactured by ULVAC-PHI, Inc.) to calculate the Zr—C ratio. After shift correction such that the C═C bond peak derived from sp² hybrid orbitals, the main component of graphite powder, was 284.2 eV¹), the C1s spectrum was separated into six peaks derived from Zr—C, C═C (sp²), C—C(sp³), C—O, O—C═O, and π-π* bonds (FIG. 2), and the Zr—C ratio when the sum of each peak area value excluding the π-π* bond was 100% was determined. The results are shown in Table 2. At this time, the position and full width at half maximum (FWHM) of each peak were fixed under the conditions shown in Table 1.

In the same manner as described above, the Zr—C ratio of the zirconia particles of other Examples and Comparative Examples was determined. The results are shown in Table 2.

TABLE 1
Curve fitting conditions for C1s

| | Position | FWHM |
|---|---|---|
| | [eV] | [—] |
| Zr—C | 283.3 | 1.25 |
| C═C | 284.2 | 0.90 |
| C—C | 284.9 | 0.95 |
| C—O | 285.8 | 1.40 |
| O—C═O | 287.8 | 1.65 |
| π-π* | 290.6 | 1.95 |

### REFERENCE LITERATURE

1) Takayuki Ohta, et al. Journal of The Surface Finishing Society of Japan, Vol. 73, No. 1, pp. 47-52, (2022).

Hence, in one aspect of the present invention, there is also provided a method for measuring the Zr—C ratio, the method including calculating the peak area value of Zr—C when the sum of the peak area values of Zr—C, C═C (sp²), C—C(sp³), C—O, and O—C═O obtained by performing waveform separation of the C1s spectrum is 100%. In one embodiment of the present invention, a reaction mixture that has undergone a mechanochemical reaction resulting from forcible collision of zirconia particles with graphite particles can be obtained, and the C1s spectrum can be obtained from that reaction mixture.

### <Measurement of Particle Size>

As the D50 value of zirconia particles, the value measured as the volume average particle size by the dynamic light scattering method using a particle size distribution measuring apparatus (UPA-UT151, manufactured by Nikkiso Co., Ltd.) was employed. Specifically, using a dispersion in which the zirconia particles were dispersed in water, the particle size of the zirconia particles was measured. Through analysis by the measuring equipment, the diameter D50 of the particles where the cumulative particle volume from the finer particle side reaches 50% of the entire particle volume in the particle size distribution of the zirconia particles was calculated.

### <Measurement of Zeta Potential>

Measurement of the zeta potential of zirconia particles was performed using a zeta potential measuring apparatus (trade name “ELS-Z”) manufactured by Otsuka Electronics Co., Ltd.

<Measurement of pH>

The pH of the polishing composition was measured with a pH meter (manufactured by HORIBA, Ltd., model number: F-71).

### [Preparation of Polishing Composition]

### Example 1

As the abrasive grains, an aqueous dispersion of colloidal zirconia with a Zr—C ratio of 15.40% and a particle size (D50) of 43 nm was prepared. This aqueous dispersion was added to the liquid medium, pure water, at room temperature (25° C.) such that the final concentration of colloidal zirconia was 0.5% by mass, with nitric acid added as the pH adjusting agent to achieve a pH of 4.5, and uniformly mixed to prepare a polishing composition. The zeta potential of the colloidal zirconia in the obtained polishing composition was 27.9 mV. Note that the crystallinity of the zirconia particles is confirmed using the peak position of the diffraction pattern by the X-ray diffraction method.

### Examples 2 to 9 and Comparative Examples 1 to 3

Polishing compositions were prepared in the same manner as in Example 1, except that colloidal zirconia was changed to the colloidal zirconia shown in Table 2 and the pH adjusting agent was changed to the pH adjusting agent shown in Table 2.

### [Polishing Removal Rate]

As the object to be polished (substrate), a monocrystalline silicon wafer on which a spin-on carbon film with a graphite structure had been deposited at a thickness of 5000 Å was prepared.

Using each of the polishing compositions obtained as described above, the prepared substrate was polished under the following polishing conditions to measure the polishing removal rate.

### (Polishing Conditions)

Polishing apparatus: FREX 300E manufactured by Ebara Corporation
Polishing pressure: 2.0 psi (1 psi=6894.76 Pa)
Platen (table) rotation speed: 60 rpm
Amount of polishing composition supplied: 300 mL/min.

### (Polishing Removal Rate)

The film thickness was determined with an X-ray fluorescence apparatus (manufactured by Rigaku Corporation, model number: ZSX400), and the polishing removal rate was evaluated by dividing the difference in film thickness before and after polishing by the polishing time (see the expression below).

$$\begin{matrix}polishing removal \\ rate [ Å / min ]\end{matrix} = \frac{[ film thickness ( Å ) of object to be polished before polishing ] - [ [ film thickness ( Å ) of object to be polished after polishing ]}{[ polishing time ( min ) ]} \qquad [ Expression 2 ]$$

### <Particle Residues>

For the measurement of particle residues, a wafer defect inspection system SP-5 manufactured by KLA-Tencor Corporation was used.

At first, the surface that had been polished was cleaned using a brush made of polyvinyl alcohol with pure water at a brush push amount of 1 mm and a rotation speed of 100 rpm for 60 seconds. Thereafter, the monocrystalline silicon substrate was rotated at a rotation speed of 1500 rpm for 60 seconds to dry it and prepare the cleaned substrate.

The target for detection was foreign substances present in the remaining portion of the cleaned substrate, excluding the 5-mm wide portion from the outer edge of one face of the cleaned substrate (the portion from 0-mm wide to 5-mm wide when the outer edge is defined as 0 mm). In such portion, the foreign substances in 100 randomly sampled field of view samples were all observed using Review SEM RS6000 manufactured by Hitachi, Ltd., and the number of those that were visually determined to be particles was confirmed.

The evaluation results for the polishing composition of each Example and each Comparative Example are shown in Table 2 below.

TABLE 2

| | | | | | | | | | Polishing | |
|---|---|---|---|---|---|---|---|---|---|---|
| | Abrasive grains (colloidal zirconia) | | | | | | | | removal | |
| | Concentration | Particle | ζ | | | Additive | | Physical | rate | |
| | % by | size | potential | | Zr-C | pH adjusting | | properties | SOC film | Particle |
| | mass | nm | mV | Crystallinity | ratio | agent | | pH | [Å/min] | residues |
| Example 1 | 0.5 | 43 | 27.9 | Mono | 15.40 | Nitric acid | | 4.5 | 2685 | 701 |
| | | | | clinic | | | | | | |
| Example 2 | 0.5 | 100 | 37.3 | Mono | 13.03 | Nitric acid | | 4.5 | 2383 | 578 |
| | | | | clinic | | | | | | |
| Example 3 | 0.5 | 34 | 28.9 | Cubic | 17.29 | Nitric acid | | 4.5 | 2989 | 879 |
| Example 4 | 0.5 | 39 | 34.0 | Cubic | 10.94 | Nitric acid | | 4.5 | 2081 | 506 |
| Example 5 | 0.5 | 20 | 30.0 | Cubic | 5.90 | Nitric acid | | 4.5 | 1132 | 612 |
| Example 6 | 0.5 | 43 | 27.9 | Mono | 15.40 | Acetic | | 4.5 | 1880 | 722 |
| | | | | clinic | | acid | | | | |
| Example 7 | 0.5 | 20 | 7.3 | Cubic | 5.90 | Acetic | TM | 4.5 | 938 | 1220 |
| | | | | | | acid | AH | | | |
| Example 8 | 0.5 | 43 | 31.1 | Mono | 15.40 | Acetic | | 3.7 | 2205 | 549 |
| | | | | clinic | | acid | | | | |
| Example 9 | 0.5 | 43 | 5.7 | Mono | 15.40 | Potassium | | 5.5 | 2377 | 1053 |
| | | | | clinic | | hydroxide | | | | |
| Comparative | 0.5 | 70 | 30.0 | Mono | 5.18 | Nitric acid | | 4.5 | 425 | 325 |
| Example 1 | | | | clinic | | | | | | |
| Comparative | 0.5 | 70 | 30.0 | Mono | 5.09 | Nitric acid | | 4.5 | 94 | 413 |
| Example 2 | | | | clinic | | | | | | |
| Comparative | 0.5 | 40 | 27.4 | Tetra | 22.17 | Nitric acid | | 4.5 | 3356 | 1559 |
| Example 3 | | | | gonal | | | | | | |

TMAH: tetramethylammonium hydroxide

The present application is based on Japanese Patent Application No. 2024-056632 filed on Mar. 29, 2024, and the contents disclosed therein are incorporated herein by reference in their entirety.

The invention claimed is:

1. A polishing composition for polishing an object to be polished, comprising abrasive grains and a liquid medium, wherein the abrasive grains comprise zirconia particles, and wherein the zirconia particles have a Zr—C ratio of 5.5 to 21%.

2. The polishing composition according to claim 1, wherein the object to be polished comprises a graphite component-containing material.

3. The polishing composition according to claim 2, wherein the object to be polished comprises a layered material of carbon atoms having sp² hybrid orbitals.

4. The polishing composition according to claim 1, wherein the abrasive grains comprise those capable of covalent bonding with the object to be polished.

5. The polishing composition according to claim 4, which is free of a component that inhibits the covalent bonding.

6. The polishing composition according to claim 5, wherein the component that inhibits the covalent bonding is a water-soluble polymer.

7. The polishing composition according to claim 1, wherein the object to be polished is substantially free of a material having metal-nitrogen bonds.

8. The polishing composition according to claim 1, which is free of an alkali compound.

9. The polishing composition according to claim 1, which is substantially free of a metal-containing oxidizing agent.

10. The polishing composition according to claim 9, which is substantially free of an oxidizing agent, except for nitric acid.

11. The polishing composition according to claim 1, having a pH of less than 6.

12. The polishing composition according to claim 11, having a pH of more than 3.7 and less than 5.5.
